(19) United States
(12) Patent Application Publication
(10) Pub. No.: US 2026/0064017 A1
(43) Pub. Date: Mar. 5, 2026

(54) SYSTEMS AND METHODS FOR DUAL-CONJUGATE IMAGING FOR OVERLAY METROLOGY

(71) Applicant: KLA Corporation, Milpitas, CA (US)

(72) Inventors: Andrew V. Hill, Berkley, CA (US); Ido Dolev, Milpitas, CA (US); Daria Negri, Nesher (IL); Oren Lahav, Adi (IL)

(21) Appl. No.: 18/825,697

(22) Filed: Sep. 5, 2024

(51) Int. Cl. G03F 7/00

(52) U.S. Cl. CPC G03F 7/706851; G03F 7/70653; G03F 7/706837

(57) ABSTRACT

A metrology system for imaging samples such as semiconductor devices having metrology targets for measuring overlay. In embodiments, a multi-channel imaging system is configured to image two relevant spaced layers of a sample simultaneously at the same magnification using a common detector. In embodiments, the multi-channel imaging system includes a first imaging light for imaging the metrology target at a first depth, and a second imaging light for imaging the metrology target at a second depth, wherein the first and second imaging lights are generating by splitting collected light from the sample, and wherein first and second sub-images associated with the respective first and second imaging lights are used to generate metrology measurements.

### TECHNICAL FIELD

The present disclosure relates generally to overlay metrology and, more particularly, to single detector dual-conjugate imaging for overlay metrology.

### BACKGROUND

Overlay metrology refers to measurements of the relative alignment of layers on a sample such as, but not limited to, semiconductor devices. An overlay measurement, or a measurement of overlay error, typically refers to a measurement of the misalignment of fabricated features on two or more sample layers. Proper alignment of fabricated features on multiple sample layers is necessary for proper functioning of the device.

Accurate overlay metrology relies on high resolution imaging of two relevant layers of a sample and for the images of the two layers to have a robust lateral spatial reference with respect to each other. Some semiconductor sample structures can have significant height resulting in highly spaced layers, for example, structures generated in wafer die bonding and 3D NAND structures. Targets for measuring overlay can be separated in height on these devices to an extent where they cannot be simultaneously imaged at high resolution using a single composite best focus position.

Traditional solutions for imaging highly spaced target structures include sequentially capturing separate images of the relevant layers while refocusing between captures, reducing the numerical aperture to extend the depth of field to include the relevant layers, and capturing separate images of the relevant layers on different cameras with each camera focused onto a different layer. The first solution is disadvantageous considering the mechanics of refocusing are prone to losing lateral registration between images. The second solution is disadvantageous in that lateral measurement precision degrades with reduced spatial resolution. The third solution is disadvantageous in that multiple cameras and optics associated with capturing separate images of each layer are costly and require a subsystem to maintain a lateral position reference between multiple cameras.

Therefore, what is needed is a solution for imaging metrology targets, and particularly highly spaced metrology target structures, that overcomes the disadvantages of prior art solutions.

### SUMMARY

A metrology system is disclosed, in accordance with one or more illustrative embodiments of the present disclosure. In one illustrative embodiment, the metrology system may include an optical system including an illumination source configured to generate an illumination beam, a multi-channel imaging system including a detector, a first imaging channel for imaging a metrology target of a sample at a first depth on a first portion of the detector, and a second imaging channel for imaging the metrology target of the sample at a second depth on a second portion of the detector, wherein the first portion and the second portion of the detector are non-overlapping, and wherein an image generated by the detector includes a first sub-image associated with the first channel and a second sub-image associated with the second channel. In embodiments, the metrology system may further include a controller including one or more processors configured to execute program instructions causing the one or more processors to implement a metrology recipe by receiving one or more images from the detector, wherein the one or more images include the one or more first sub-images and the one or more second sub-images, and generating one or more metrology measurements of the sample based on the received one or more first sub-images and the one or more second sub-images.

In some embodiments, the first imaging channel and the second imaging channel may include double telecentric image relays.

In some embodiments, focused depths of the first imaging channel and the second imaging channel may be separately adjustable.

In some embodiments, the system may further include a beam splitter configured to split light collected from the sample into a first imaging light corresponding to the first imaging channel, and a second imaging light corresponding to the second imaging channel.

In some embodiments, the light source may be temporally coherent or incoherent.

In some embodiments, the first depth may correspond to a first layer of the sample having one or more first target structures, and the second depth may correspond to a second layer of the sample having one or more second target structures.

In some embodiments, the metrology target may include at least one of an advanced imaging metrology (AIM) target or a robust AIM target.

In some embodiments, the one or more first target structures and the one or more second target structures may be at least partially non-overlapping.

In some embodiments, the multi-channel imaging system may be configured to image the first and second layers simultaneously and at the same magnification.

A metrology system is disclosed, in accordance with one or more illustrative embodiments of the present disclosure. In one illustrative embodiment, the metrology system may include a controller including one or more processors configured to execute program instructions causing the one or more processors to implement a metrology recipe by receiving one or more images from a detector, wherein the one or more images include one or more first sub-images of a metrology target from a first portion of the detector and one or more second sub-images of the metrology target from a second portion of the detector, wherein the one or more first sub-images are generated by a first imaging channel of a multi-channel imaging system and correspond to a first depth of a sample, and wherein the one or more second sub-images are generated by a second imaging channel of a multi-channel imaging system and correspond to a second depth of the sample, and generating one or more metrology measurements of the sample based on the one or more first sub-images and the one or more second sub-images.

A metrology method is disclosed, in accordance with one or more illustrative embodiments of the present disclosure. In one illustrative embodiment, the method includes receiving one or more images from a detector, wherein the one or more images include one or more first sub-images of a metrology target from a first portion of the detector and one or more second sub-images of the metrology target from a second portion of the detector, wherein the one or more first sub-images are generated by a first imaging channel of a multi-channel imaging system and correspond to a first depth of a sample, and wherein the one or more second sub-images are generated by a second imaging channel of a multi-channel imaging system and correspond to a second depth of the sample, and generating one or more metrology measurements of the sample based on the one or more first sub-images and the one or more second sub-images.

In some embodiments, the first imaging channel corresponds to a first imaging light, the second imaging channel corresponds to a second imaging light, and the first imaging light and the second imaging light are formed by a beam splitter configured to split light collected from the sample.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, explain the principles of the invention.

### BRIEF DESCRIPTION OF THE DRAWINGS

The numerous advantages of the disclosure may be better understood by those skilled in the art by reference to the accompanying figures.

FIG. 1 is a block diagram of a metrology system for imaging overlay metrology targets, in accordance with one or more embodiments of the present disclosure.

FIG. 2 is a schematic diagram of an optical system for imaging overlay metrology targets, in accordance with one or more embodiments of the present disclosure.

FIG. 3 is a schematic diagram of sub-images for forming an exemplary metrology target image on a detector, in accordance with one or more embodiments of the present disclosure.

FIG. 4 is a schematic diagram of an exemplary metrology target, in accordance with one or more embodiments of the present disclosure.

FIG. 5 is a schematic diagram of a double-telecentric image relay system, in accordance with one or more embodiments of the present disclosure.

FIG. 6 is a flowchart of a method for imaging metrology targets, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

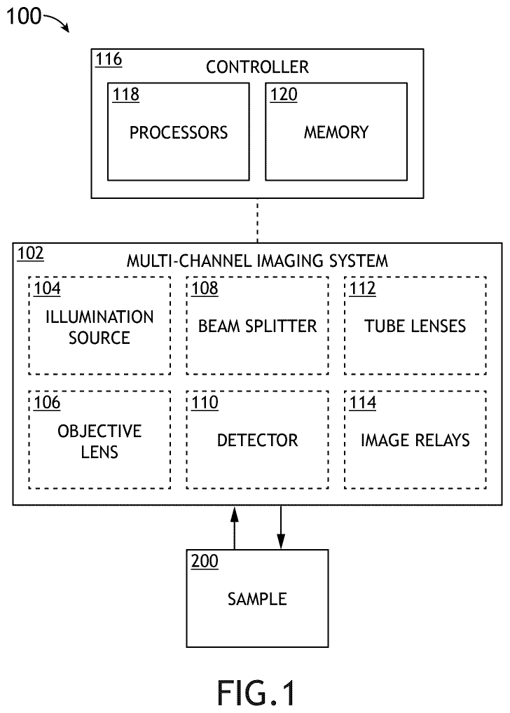

Referring to FIGS. 1 through 4, systems and methods for imaging overlay metrology targets are disclosed, in accordance with one or more embodiments of the present disclosure.

Embodiments of the present disclosure are directed to systems and methods for simultaneously imaging two different layers of a sample, for instance a semiconductor device, at the same magnification and using a single detector (e.g., sensor, camera, etc.). In embodiments, a multi-channel imaging system includes first and second independently focusable imaging channels for imaging a metrology target at first and second depths in a sample, and generating sub-images associated with the first and second channels used to generate metrology measurements. The multi-channel imaging system according to the present disclosure provides the flexibility to independently adjust focus in each image without laterally shifting images or changing magnification, provides stable spatial registration between the two images, obviates the need for multiple imaging detectors, and eliminates the need for subsystems for monitoring relative registration between two detectors, among other benefits and advantages. In addition, the multi-channel imaging system according to the present disclosure reduces the overall system size, complexity, part count, and cost.

For purposes of the present disclosure, the term sample broadly encompasses any physical sample including metrology targets or regions of interest, for instance semiconductor devices including registered layers and high topography semiconductor stacks.

Referring to FIG. 1, a block diagram of a metrology system 100 for overlay metrology is shown in accordance with one or more embodiments of the present disclosure. While FIG. 1 shows various components grouped as part of sub-systems of the overall system, it is understood that the various components may be grouped as part of separate systems or sub-systems that operate together to perform as described in detail below. For example, certain components for generating, collecting, and splitting light may be grouped in one sub-system, whereas other components for handling the imaging light and generating images may be grouped into another separate sub-system.

In embodiments, the metrology system 100 includes a multi-channel imaging system 102 for imaging a metrology target to perform overlay measurements on a sample 200 such as a semiconductor device. In embodiments, the metrology system 100 includes one or more illumination sources 104 for generating an initial illumination beam, an objective lens 106 for collecting light directed to the metrology target on the sample 200, and a beam splitter 108 for splitting the collected light from the metrology target into a first imaging light forming a first channel and a second imaging light forming a second channel. The beam splitter 108 may function to split the collected light in terms of amplitude, by polarization, by spectral content, or any combination thereof. In embodiments, the beam splitter 108 may be interchanged with different types of beam splitters depending on the desired imaging parameters per layer of the sample 200. In embodiments, the optical system may include a single illumination source. In embodiments, when reflections are required by beam splitters and mirrors, both channels may have an even number of reflections or both channels may have an odd number of reflections to match image orientations at the detector 110.

The multi-channel imaging system 102 further includes first and second tube lenses 112 for focusing the first and second imaging light and for forming telecentric intermediate images for each of the first and second channels. In embodiments, magnification at intermediate fields formed by the tube lenses 112 may be less than the magnification of the final images at the detector 110. The tube lenses 112 may be common (i.e., shared) for the two illumination beams or separate.

In embodiments, the multi-channel imaging system 102 further includes double telecentric image relays 114 on the first and second channels forming the final images on the detector 110. Lenses within the double telecentric image relays 114 may be intentionally decentered to closely space or ‘pack’ the two images, and the double telecentric image relays 114 may be separately adjustable to set the focus for each image. In embodiments, magnification of the double telecentric image relays 114 may be greater than 1×. In embodiments, the double telecentric image relays 114 may generate off-axis image and position zooming to change the image focus without laterally shifting the image position or changing magnification. In embodiments, the detector 110 may include any type of optical detector known in the art suitable for capturing light.

In embodiments, the metrology system 100 further includes a controller 116 including one or more processors 118 and a memory device 120, or memory. For example, the one or more processors 118 may be configured to execute a set of program instructions maintained in the memory device 120. The one or more processors 118 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 118 may include any device configured to execute algorithms and/or instructions (e.g., program instructions stored in memory). In embodiments, the one or more processors 118 may be embodied as a desktop computer, mainframe computer system, workstation, image computer, parallel processor, networked computer, or any other computer system configured to execute a program configured to operate or operate in conjunction with the metrology system 100. Moreover, different subsystems of the metrology system 100 may include a processor or logic elements suitable for carrying out at least a portion of the steps described herein. Further, the steps described herein may be carried out by a single controller or, alternatively, multiple controllers. Further, the controller 116 may analyze or otherwise process data received from the detectors 110 and feed the data to additional components within the metrology system 100 or external to the metrology system 100.

The memory device 120 may include any storage medium known in the art suitable for storing program instructions executable by the associated one or more processors 118. For example, the memory device 120 may include a non-transitory memory medium. As an additional example, the memory device 120 may include, but is not limited to, a read-only memory, a random-access memory, a magnetic or optical memory device (e.g., disk), a magnetic tape, a solid-state drive and the like. It is further noted that memory device 120 may be housed in a common controller housing with the one or more processors 118.

The controller 116 may execute any of various processing steps associated with overlay metrology. For example, the controller 116 may be configured to generate control signals to direct or otherwise control the metrology system 100, or any components thereof. For instance, the controller 116 may be configured to receive images of a metrology target from the detector 110, for instance images generated from first and second sub-images corresponding to the first and second channels corresponding to first and second layers of the sample 200. By way of another example, the controller 116 may generate corrections for one or more additional fabrication tools as feedback and/or feed-forward control of the one or more additional fabrication tools based on overlay measurements from the multi-channel imaging system 102. In embodiments, the controller 116 receives the images of the metrology target and generates one or more metrology measurements of the sample 200.

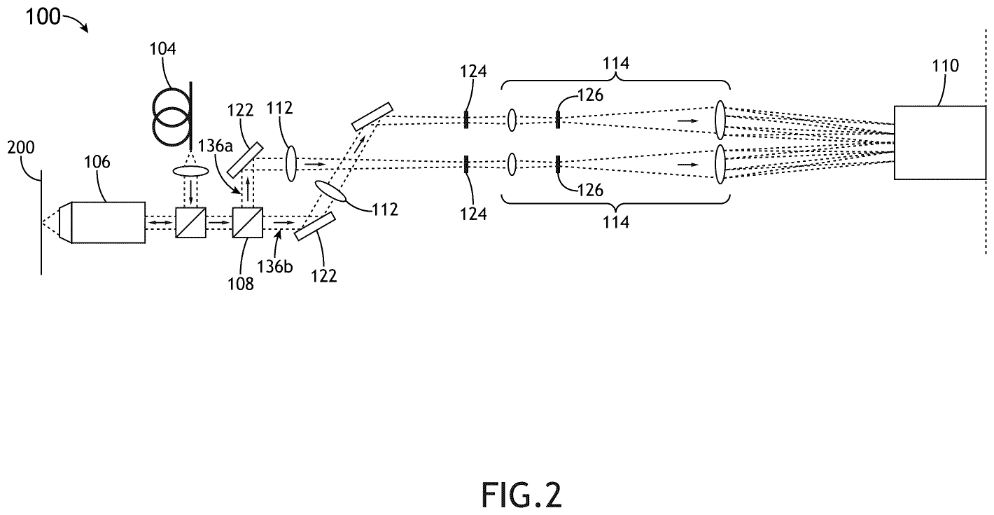

Referring to FIG. 2, a schematic diagram illustrating an exemplary arrangement of the components of the optical portion of the metrology system 100 is shown in accordance with one or more embodiments of the present disclosure. As shown, the objective lens 106 is positioned relative to the sample 200 to focus the illumination beam onto the sample 200, and to collect measurement light emanating from the sample 200 in response to the illumination beam. In embodiments, the one or more illumination sources 104 are configured to generate illumination to illuminate the sample 200. The one or more illumination beams may be spatially limited to illuminate predefined portions of the sample 200, for instance a particular metrology target provided in layers.

The one or more illumination sources 104 may include any type of illumination source suitable for providing at least one illumination beam. In embodiments, the illumination source may be a laser source. In this regard, the illumination beam may have a high coherence (e.g., high spatial coherence and/or temporal coherence). The one or more illumination source 104 may be a component of an illumination sub-system including one or more optical components for modifying and/or conditioning the illumination beam as well as directing the illumination beam to the sample 200. For example, further components may include, but are not limited to, lenses and control optics (e.g., field stops, pupil stops, polarizers, filters, diffusers, homogenizers, apodizers, shapers, mirrors, etc.).

The light collected from the metrology target is split by the beam splitter 108 into a first imaging light 136a and a second imaging light 136b. In embodiments, the first imaging light 136a corresponds to a first portion of the metrology target, for instance the first depth corresponding to a first layer of the sample 200, and the second imaging light 136b corresponds to a second portion of the metrology target, for instance the second depth corresponding to a second layer of the sample 200. In some embodiments, the first and second imaging lights 136a, 136b may be reflected by at least one set of mirrors 122 for directing the first and second imaging lights 136a, 136b along parallel pathways. In embodiments, the number of reflections of the first and second imaging lights 136a, 136b may match.

The tube lenses 112 form telecentric intermediate images on telecentric intermediate images planes 124. The first and second double telecentric images relays 114, corresponding to the first and second imaging lights 136a, 136b, include collection pupil planes 126 positioned near the detector 110. In embodiments, the optical system may further include additional polarization or spectral filters per channel.

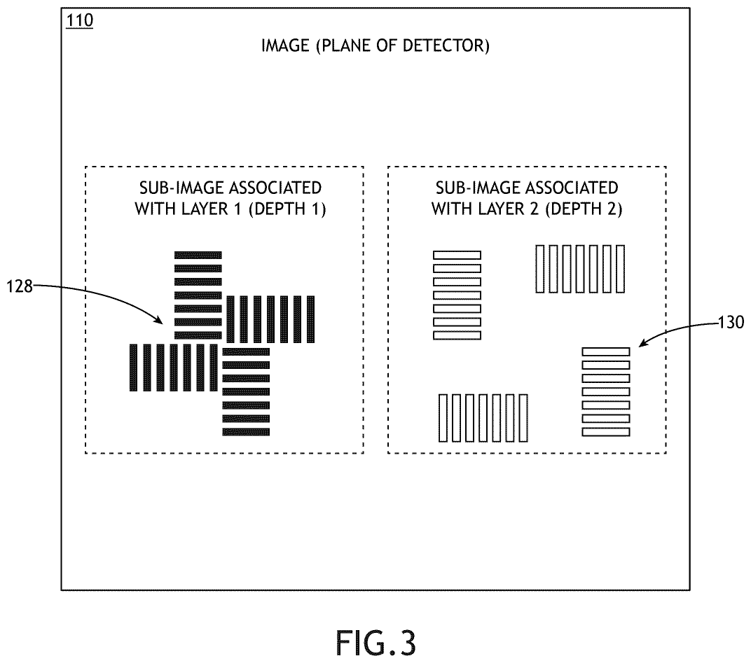

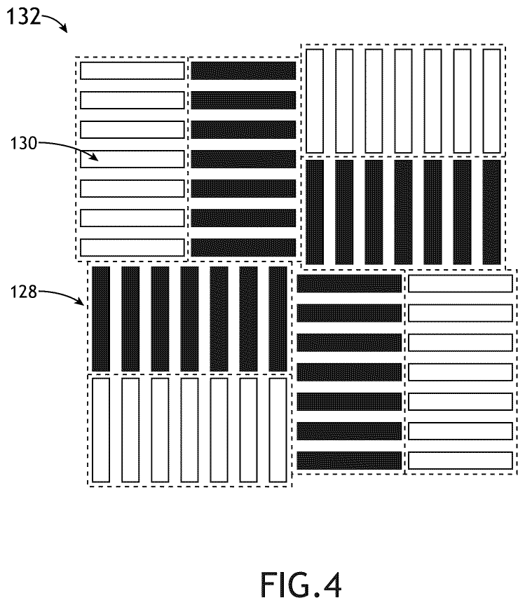

Referring to FIG. 3, the light from the first and second imaging lights 136a, 136b is received on different portions of the detector 110 as separate sub-images. In embodiments, the light from the first imaging light 136a associated with the first layer of the sample 200 is received on a first portion of the detector 110, and the light from the second imaging light 136b associated with the second layer of the sample 200 is received on a second portion of the detector 110. The first and second portions, which may be non-overlapping, correspond to first and second sub-images for forming one or more images of the metrology target (e.g., AIM target) used by the controller to generate one or more metrology measurements. As shown, in a non-limiting example, the first sub-image associated with the first layer may include solid features according to a first pattern 128, and the second sub-image associated with the second layer may include open features according to a second pattern 130 different from the first pattern, wherein the patterns 128, 130 together form an AIM target 132 as shown in FIG. 4. In the case where the layers are separated by a significant enough distance as contemplated by the present disclosure, the features of non-imaged layer may be so blurred as to be effectively not present (thus the features from one figure are not shown in the other figure).

In some embodiments, the collected light may be split into more than two imaging lights corresponding to more than two channels. For example, more than one beam splitter 108 or a mirrored prism may be used to split the collected light to form more than two channels, and additional double telecentric image relays 114 may be used to provide additional sub-images of the metrology target(s). In a particular conceived example, more than one sub-image may be obtained from the first depth via more than one of the first imaging lights, and more than one sub-image may be obtained from the second depth via more than one of the second imaging lights. Each of the plurality of sub-images may be used to form one or more images of the metrology target.

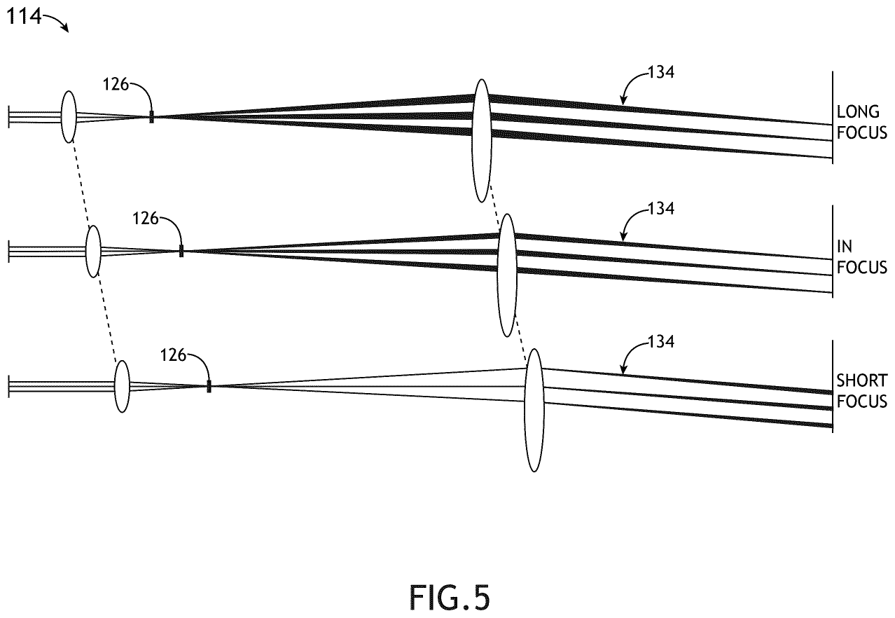

Referring to FIG. 5, non-limiting examples of focal positions of the double telecentric image relays 114 for generating off-axis image and position zooming to change the image focus without laterally shifting the image position or changing magnification are shown in accordance with one or more embodiments of the present disclosure. As shown, the position of the features in the sub-images are stationary (e.g., no lateral shifting) regardless of the focal position (e.g., long focus, in focus, short focus, etc.). In particular, the center points of the three ray bundles 134 on the detector 110 do not shift as the focus is adjusted. In addition, the two or more image positionings can be made, for example, converging to closely pack the two images. In embodiments, the system provides the flexibility to separately (i.e., independently) adjust the first and second imaging channels in terms of focused depth, image position, etc.

The metrology system 100 may be configured for certain types of devices or features of a sample 200 according to a “metrology recipe.” For instance, the metrology system 100 may be programmed to calculate overlay measurements of certain types of features according to a metrology recipe (e.g., methodology, process, program instructions, and/or the like). The present disclosure is not limited to any particular type or configuration of respective first and second target features forming a metrology target when fixedly placed one upon another.

Referring again to FIG. 4, a non-limiting example of a metrology target 132 according to the present disclosure may include one or more first target features 128 (e.g., structures) formed on a first layer of a semiconductor device, and one or more second target features 130 (e.g., structures) formed on at least a second layer of the semiconductor device, wherein the first layer corresponds to the first depth of the device and the second layer corresponds to the second depth of the device. In embodiments, the metrology target may correspond to the combined structure formed by first and second target features when the first and second layers are fixedly placed one upon the other. The first and second target features 128, 130 may be disposed in a fixed position with respect to each other such that metrology may be performed upon the metrology target 132 to measure possible misregistration between the relevant layers, wherein overlay is determined as a difference between centers of symmetry of features in different layers, for instance the first and second target features 128, 130.

In a particular conceived example, the first and second layers may be consecutive layers of a semiconductor device such as a 3D NAND semiconductor device, a DRAM semiconductor device, a FOUNDRY/LOGIC semiconductor device, etc. In a further conceived example, the first and second layers may be embodied as consecutive wafer layers in wafer-to-wafer stacking or consecutive layers of wafer and die in die-to-wafer stacking.

In embodiments, first and second target features forming the metrology target 132 may have a positional relationship, for instance different orders of rotational symmetry such that the first and the second layer features are at least partially non-overlapping. For example, first target features may be formed by first dimensioned elements having a first order of rotational symmetry and second target features may be formed by second dimensioned elements having a second order or rotational symmetry different from the first order of rotational symmetry. The metrology system 100 according to the present disclosure is particularly advantageous for overlay measurements associated with high topography stacks, for instance layers having topographical features of height greater than 4 um or greater than 5 um. Similarly, the metrology system 100 according to the present disclosure is advantageous over periodic targets, such as conventional Advanced Imaging Metrology (AIM) targets, since target elements formed on high topography layers may require mutual separation by a minimum distance. In a further embodiment, the metrology targets may include multi-layer targets for determining misregistration between three or more layers of a semiconductor device.

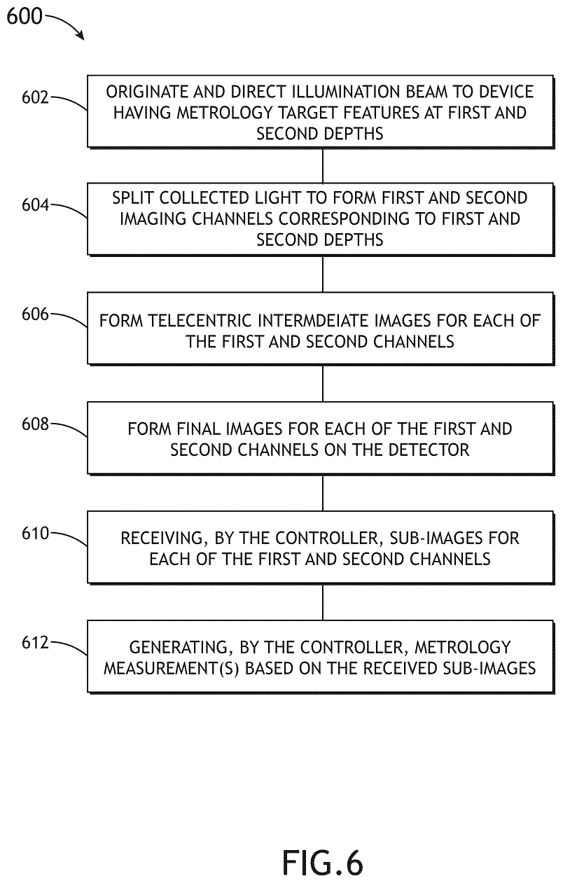

Referring to FIG. 6, a flow chart of a method 600 for overlay metrology utilizing the metrology system according to the present disclosure is shown in accordance with one or more embodiments. It is noted that the embodiments and enabling technologies described previously herein in the context of the metrology system 100 should be interpreted to extend to the method 600. It is further noted herein that the steps of the method 600 may be implemented all or in part by metrology system 100. It is further recognized, however, that the method 600 is not limited to the metrology system 100 in that additional or alternative system-level embodiments may carry out all or part of the steps of method 600.

In step 602, an illumination beam is originated and directed to a sample 200 to illuminate a metrology overlay target formed by one or more first features at a first depth of the sample 200 and one or more second features at a second depth of the sample 200. In step 604, light collected from the metrology target is split by the beam splitter 108 to form a first imaging light 136a corresponding to the first depth of the sample 200, and a second imaging light 136b corresponding to the second depth of the sample 200. In step 606, the first and second imaging lights 136a, 136b are handled by tube lenses 112 to form telecentric intermediate images on each channel. In a step 608, double telecentric image relays 114 form the final images on each channel which are formed on the detector 110. In step 610, the method 600 continues with the controller 116 receiving the images from the detector 110, wherein the images include one or more sub-images from each channel. In step 612, the method 600 concludes with the controller 116 generating one or more metrology measurements based on the received sub-images from the channels.

The overlay measurement can be given in various units of measure or can be dimensionless. In use, if the overlay measurement is greater than a predetermined threshold, then the process parameter(s) may be adjusted to reduce the overlay error. Conversely, if the overlay measurement is less than the predetermined threshold, then the process parameter(s) might be left unchanged, or possibly adjusted to decrease the overlay slightly to keep it within an optimal range.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

This disclosure is presented to enable one of ordinary skill in the art to make and use the invention as provided in the context of a particular application and its requirements. Various modifications to the described embodiments will be apparent to those with skill in the art, and the general principles defined herein may be applied to other embodiments. Therefore, the present invention is not intended to be limited to the particular embodiments shown and described but is to be accorded the widest scope consistent with the principles and novel features herein disclosed.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A metrology system comprising:
a light source configured to generate an illumination beam;
a multi-channel imaging system comprising:
a detector;
a first imaging channel for imaging a metrology target on a sample at a first depth on a first portion of the detector; and
a second imaging channel for imaging the metrology target on the sample at a second depth on a second portion of the detector, wherein the first portion and the second portion of the detector are non-overlapping, and wherein an image generated by the detector includes a first sub-image associated with the first channel and a second sub-image associated with the second channel; and
a controller including one or more processors configured to execute program instructions causing the one or more processors to implement a metrology recipe by:
receiving one or more images of the metrology target from the detector, wherein the one or more images include the one or more first sub-images and the one or more second sub-images; and
generating one or more metrology measurements of the sample based on the one or more first sub-images and the one or more second sub-images.

2. The metrology system of claim 1, wherein the first imaging channel and the second imaging channel include double telecentric image relays.

3. The metrology system of claim 1, wherein focused depths of the first imaging channel and the second imaging channel are separately adjustable.

4. The metrology system of claim 1, further comprising a beam splitter configured to split light collected from the metrology target into a first imaging light corresponding to the first imaging channel, and a second imaging light corresponding to the second imaging channel.

5. The metrology system of claim 1, wherein the light source is temporally coherent or incoherent.

6. The metrology system of claim 1, wherein the first depth corresponds to a first layer of the sample having one or more first target structures, and the second depth corresponds to a second layer of the sample having one or more second target structures.

7. The metrology system of claim 6, wherein the metrology target comprises:
at least one of an advanced imaging metrology (AIM) target or a robust AIM target.

8. The metrology system of claim 6, wherein the one or more first target structures and the one or more second target structures are at least partially non-overlapping.

9. The metrology system of claim 6, wherein the multi-channel imaging system is configured to image the first and second layers simultaneously and at the same magnification.

10. A metrology system comprising:
a controller including one or more processors configured to execute program instructions causing the one or more processors to implement a metrology recipe by:
receiving one or more images of a metrology target from a detector, wherein the one or more images include one or more first sub-images of the metrology target from a first portion of the detector and one or more second sub-images of the metrology target from a second portion of the detector;
wherein the one or more first sub-images are generated by a first imaging channel of a multi-channel imaging system and correspond to a first depth of a sample, and the one or more second sub-images are generated by a second imaging channel of a multi-channel imaging system and correspond to a second depth of the sample; and
generating one or more metrology measurements of the sample based on the one or more first sub-images and the one or more second sub-images.

11. The metrology system of claim 10, wherein the first imaging channel and the second imaging channel include double telecentric image relays.

12. The metrology system of claim 10, wherein focused depths of the first imaging channel and the second imaging channel are separately adjustable.

13. The metrology system of claim 10, wherein:
the first imaging channel corresponds to a first imaging light;
the second imaging channel corresponds to a second imaging light; and
the first imaging light and the second imaging light are provided by a beam splitter configured to split light collected from the sample.

14. The metrology system of claim 13, wherein the light collected from the sample is provided by light originating from an illumination source configured to illuminate the first and second depths of the sample.

15. The metrology system of claim 10, wherein:
the first depth of the sample corresponds to a first layer of the sample having one or more first target structures;
the second depth of the sample corresponds to a second layer of the sample having one or more second target structures; and
the first and second target structures collectively form the metrology target.

16. The metrology system of claim 15, wherein the one or more first target structures and the one or more second target structures are at least partially non-overlapping.

17. The metrology system of claim 15, wherein the multi-channel imaging system is configured to image the first layer and the second layer simultaneously and at the same magnification.

18. The metrology system of claim 10, wherein the metrology target comprises:
at least one of an advanced imaging metrology (AIM) target or a robust AIM target.

19. A metrology method comprising:
receiving one or more images of a metrology target from a detector, wherein the one or more images include one or more first sub-images of the metrology target from a first portion of the detector and one or more second sub-images of the metrology target from a second portion of the detector, wherein the one or more first sub-images are generated by a first imaging channel of a multi-channel imaging system and correspond to a first depth of a sample, and the one or more second sub-images are generated by a second imaging channel of a multi-channel imaging system and correspond to a second depth of the sample; and
generating one or more metrology measurements of the sample based on the one or more first sub-images and the one or more second sub-images.

20. The metrology method of claim 19, wherein:
the first imaging channel corresponds to a first imaging light, the second imaging channel corresponds to a second imaging light, and the first imaging light and the second imaging light are formed by a beam splitter configured to split light collected from the sample;
the one or more first sub-images and the one or more second sub-images are obtained by the multi-channel imaging system simultaneously and at the same magnification;
focused depths of the first imaging channel and the second imaging channel are separately adjustable; and
the first depth corresponds to a first layer of the sample having one or more first target structures, and the second depth corresponds to a second layer of the sample having one or more second target structures.
